(19) United States
(12) Patent Application Publication
(10) Pub. No.: US 2014/0103311 A1
(43) Pub. Date: Apr. 17, 2014

(54) OLED LIGHTING DEVICE AND METHOD FOR MANUFACTURING THE SAME

(71) Applicant: Ultimate Image Corporation, Miaoli County (TW)

(72) Inventor: Chih-Feng SUNG, Miaoli County (TW)

(73) Assignee: Ultimate Image Corporation, Miaoli County (TW)

(21) Appl. No.: 14/041,265

(22) Filed: Sep. 30, 2013

(30) Foreign Application Priority Data
Oct. 12, 2012 (TW) 101137761

(51) Int. Cl. H01L 51/52

(52) U.S. Cl. CPC H01L 51/5206; H01L 51/5221
USPC 257/40; 438/22

(57) ABSTRACT

An organic light-emitting diode (OLED) lighting device includes a substrate, at least a conductive wire, an insulating layer, a first electrode layer, an organic light-emitting layer and a second electrode layer. The conductive wire is disposed on the substrate and has a top surface away from the substrate. The insulating layer is disposed on the substrate and has an upper surface away from the substrate. At least a part of the top surface of the conductive wire is exposed from the insulating layer. The first electrode layer is disposed to cover the upper surface of the insulating layer, and is electrically connected with the conductive wire. The organic light-emitting layer is disposed on the first electrode layer. The second electrode layer is disposed on the organic light-emitting layer. In addition, a method for manufacturing the OLED lighting device is provided.

### FIELD OF THE INVENTION

The invention relates to a lighting device, and more particularly to an organic light-emitting diode lighting device, and a method for manufacturing the same.

### BACKGROUND OF THE INVENTION

Organic light-emitting diodes (OLEDs) have attracted extensive attention in display and lighting applications since they have several advantages such as self-luminous, low power source consumption and fast response time. OLED electrically excites a light-emitting layer of a fluorescent or phosphorescent organic compound to emit light.

In most of existing OLED devices, a conductive thin film is used as an electrode for carrying current to the light-emitting layer, which is difficult to carry a large current due to the limitation of resistance, and leads to an inevitable power loss. This problem becomes more pronounced especially in the field of lighting. Therefore, additional shunt electrodes are used to assist the transmission of the large current.

FIG. 1 is a sectional schematic diagram showing an OLED lighting device. As shown in FIG. 1, a transparent electrode 12 and a shunt electrode 13 are sequentially formed on a substrate 11. The shunt electrode 13 is electrically connected to the transparent electrode 12. Since the thickness of the shunt electrode 13 is obviously greater than that of the transparent electrode 12, the shunt electrode 13 with a low resistance can be used to transport a large current, so that the power loss can be effectively decreased.

However, the thickness sum of the shunt electrode 13 and the insulating layer 14 is much larger than the thickness of an organic light-emitting layer 15 or a metal electrode 16. This leads to a thickness unevenness of the organic light-emitting layer 15 deposited on the substrate 11, and leads to a crack 17 at a bent part of the metal electrode 16 subsequently deposited on the organic light-emitting layer 15.

### SUMMARY OF THE INVENTION

One object of the invention is to provide an organic light-emitting diode (OLED) lighting device, so as to solve the above-mentioned problems of uneven thickness of the organic light-emitting layer and cracks occurred at the bent part of the electrode.

The invention provides an OLED lighting device, including a substrate, at least a conductive wire, an insulating layer, a first electrode layer, an organic light-emitting layer and a second electrode layer. The conductive wire is disposed on the substrate and has a top surface away from the substrate. The insulating layer is disposed on the substrate and has an upper surface away from the substrate, wherein at least a part of the top surface of the conductive wire is exposed from the insulating layer. The first electrode layer is disposed to cover the upper surface of the insulating layer, and is electrically connected with the conductive wire. The organic light-emitting layer is disposed on the first electrode layer. The second electrode layer is disposed on the organic light-emitting layer.

In an embodiment of the invention, the upper surface of the insulating layer is substantially flush with the top surface of the conductive wire, and a height difference between the upper surface of the insulating layer and the top surface of the conductive wire is less than 100 nm.

In an embodiment of the invention, the organic light-emitting layer and the second electrode layer extend continuously in parallel to each other.

In an embodiment of the invention, the conductive wire extends linearly on the substrate.

In an embodiment of the invention, a plurality of conductive wires are arranged in parallel on the substrate.

Another object of the invention is to provide a method for manufacturing an OLED lighting device, so as to solve the above-mentioned problems of uneven thickness of the organic light-emitting layer and cracks occurred at a bent part of an electrode.

The method for manufacturing an OLED lighting device according to the invention, including the following steps. First, a substrate is provided. Then, at least a conductive wire is formed on the substrate, wherein the conductive wire has a top surface away from the substrate. Next, an insulating layer is formed on the substrate, wherein the insulating layer has an upper surface away from substrate and at least a part of the top surface of the conductive wire is exposed from the insulating layer. Then, a first electrode layer is formed to cover the upper surface of the insulating layer, such that the first electrode layer and the conductive wire are electrically connected. Next, an organic light-emitting layer is formed on the first electrode layer. Finally, a second electrode layer is formed on the organic light-emitting layer.

In an embodiment of the invention, the upper surface of the insulating layer is substantially flush with the top surface of the conductive wire, and a height difference between the upper surface of the insulating layer and the top surface of the conductive wire is less than 100 nm.

In an embodiment of the invention, the organic light-emitting layer and the second electrode layer extend continuously in parallel to each other

Since the first electrode layer, the organic light-emitting layer and the second electrode layer are disposed on the conductive wire and the insulating layer such that they extend continuously in parallel to each other, conventional problems of thickness uneven of the organic light-emitting layer and cracks occurred at a bent part of an electrode can be solved, and thus a light-emitting uniformity of the OLED lighting device can be increased.

### BRIEF DESCRIPTION OF THE DRAWINGS

The invention will become more readily apparent to those ordinarily skilled in the art after reviewing the following detailed description and accompanying drawings, in which:

FIG. 1 is a sectional schematic diagram showing a conventional organic light-emitting diode (OLED) lighting device.

FIG. 2 is a sectional view showing an OLED lighting device according to an embodiment of the invention.

FIG. 3 is another sectional view showing an OLED lighting device according to an embodiment of the invention.

FIG. 4 is a top view schematic diagram showing an OLED lighting device according to an embodiment of the invention.

FIG. 5 is a top view schematic diagram showing an OLED lighting device according to an embodiment of the invention.

FIG. 6 is a flowchart showing a method for manufacturing an OLED lighting device according to an embodiment of the invention.

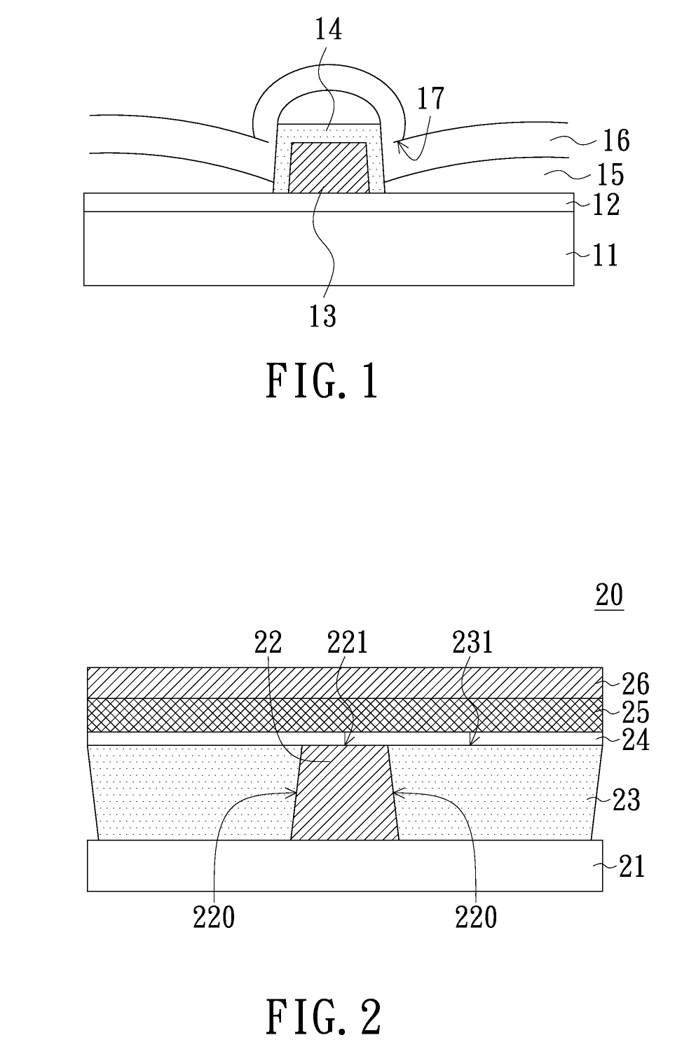

### DETAILED DESCRIPTION OF PREFERRED EMBODIMENTS

The invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

FIG. 2 is a sectional schematic diagram showing an organic light-emitting diode (OLED) lighting device 20 according to an embodiment of the invention. As shown in FIG. 2, the OLED lighting device 20 includes a substrate 21, a conductive wire 22, an insulating layer 23, a first electrode layer 24, an organic light-emitting layer 25, and a second electrode layer 26.

The substrate 21 is a transparent substrate made of glass or plastic. The conductive wire 22 is disposed on the substrate 21. The conductive wire 22 is made of metal. The conductive wire 22 has two lateral surfaces 220 and a top surface 221, wherein the two lateral surfaces 220 extend upwardly form a surface of the substrate 21, and the top surface 221 connects top edges of the two lateral surfaces 220 and extends away from the substrate 21. At least a part of the top surface 221 is exposed from the insulating layer 23.

The insulating layer 23 is disposed on the substrate 21 and at both sides of the conductive wire 22, wherein the insulating layer 23 is contacted with the two lateral surfaces 220 of the conductive wire 22. The insulating layer 23 has an upper surface 231 away from the substrate 21, and the thickness of the insulating layer 23 substantially equals to the thickness of the conductive wire 22, such that the upper surface 231 of the insulating layer 23 is substantially flush with the top surface 221 of the conductive wire 22. The insulating layer 23 is at least partially transparent and is made of an inorganic material or an organic material. An example of the inorganic material is silicon nitride or silicon dioxide, while an example of the organic material is bisbenzocyclobutene (BCB) or polymer PC403.

The first electrode layer 24 is disposed to cover the top surface 221 of the conductive wire 22 and the upper surface 231 of the insulating layer 23. The first electrode layer 24 is a transparent conductive film that is at least partially transparent, and is electrically connected with the top surface 221 of the conductive wire 22. The organic light-emitting layer 25 is disposed on the first electrode layer 24. The organic light-emitting layer 25 includes, for example, an electron transport layer, and an electroluminescent layer and a hole transport layer. The second electrode layer 26 is disposed on the organic light-emitting layer 25. The second electrode layer 26 may be, for example, an opaque metal thin film, or a light-transmissive transparent conductive film. It should be noted that the first electrode layer 24, the organic light-emitting layer 25 and the second electrode layer 26 continuously extend above the conductive wire 22 and the insulating layer 23 in parallel to one another, without any level difference or any bent part.

When a voltage is applied, a current flows from the conductive wire 22 to the first electrode layer 24, and then to the second electrode layer 26 via the organic light-emitting layer 25. Negatively charged electrons move from the second electrode layer 26 to the organic light-emitting layer 25, while positively charged holes move from the first electrode layer 24 to the organic light-emitting layer 25. When the negatively charged electrons and the positively charged holes meet in the organic light-emitting layer 25, they recombine and emit photons. The photons are emitted to outside through the first electrode layer 24, the insulating layer 23 and the substrate 21.

Since the top surface 221 of the conductive wire 22 is substantially flush with the upper surface 231 of the insulating layer 23, they substantially constitute a flat plane, such that the first electrode layer 24, the organic light-emitting layer 25 and the second electrode layer 26 extend continuously on the conductive wire 22 and the insulating layer 23 in parallel to one another. Since there is no bent part in the first electrode layer 24, the organic light-emitting layer 25 and the second electrode layer 26, the thickness of each layer is uniform, and thus a crack can be prevented. In this way, light-emitting uniformity of the OLED lighting device 20 can be effectively increased.

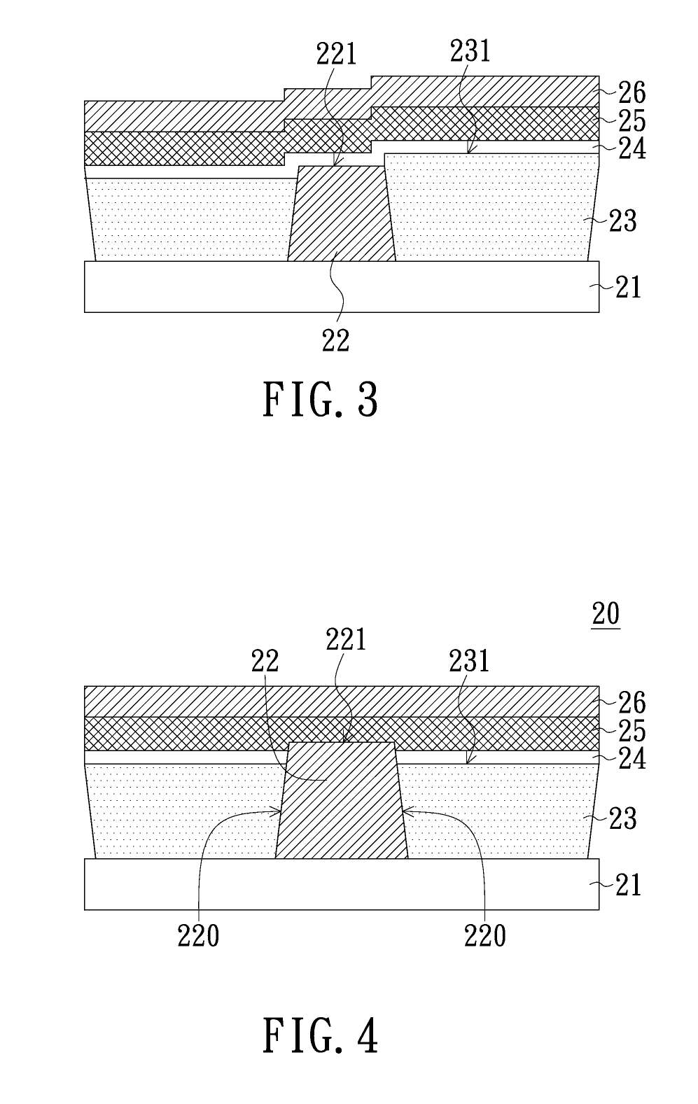

The insulating layer 23 can be suitably formed, but not limited to, by a deposition method such as vapor deposition or sputtering. As shown in FIG. 3, the upper surface 231 of the insulating layer 23 may be slightly lower or slightly higher than the top surface 221 of the conductive wire 22 depending on different deposition methods or conditions. However, it should be noted that a height difference between the upper surface 231 of the insulating layer 23 and the top surface 221 of the conductive wire 22 is limited to be less than 100 nm, so as to prevent cracks caused by a largely bent part.

FIG. 4 is a top view schematic diagram showing an OLED lighting device according to an embodiment of the invention. The OLED lighting device of this embodiment is substantially the same as the embodiment shown in FIG. 2, except that the thickness of the insulating layer 23 is thinner than that of the conductive wire 22, and the first electrode layer 24 is disposed to cover the upper surface of the insulating layer 23 but not to cover the top surface 221 of the conductive wire 22. That is, the first electrode layer 24 is disposed on both sides of the conductive wire 22 and connected to two lateral surfaces 220 of the conductive wire 22, respectively.

In this embodiment, the thickness sum of the insulating layer 23 and the first electrode layer 24 is substantially equal to the thickness of the conductive wire 22, such that the top surface 221 of the conductive wire 22 is substantially flush with the upper surface of the first electrode layer 24. The top surface 221 of the conductive wire 22 and an upper surface of the first electrode layer 24 substantially constitute a flat plane, such that the organic light-emitting layer 25 and the second electrode layer 26 extend continuously on the conductive wire 22 and the first electrode layer 24 in parallel to each other, without any level difference or any bent part.

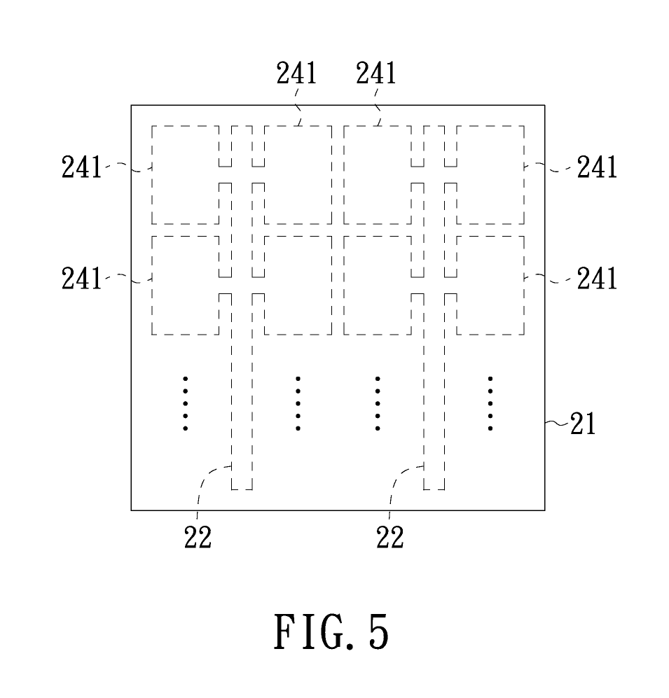

FIG. 5 is a top view schematic diagram showing an OLED lighting device 20 according to an embodiment of the invention. In this embodiment, a plurality of conductive wires 22 are arranged in parallel on the substrate 21, wherein each conductive wire 22 is linear. Actually, the first electrode layer 24 has multiple electrode blocks 241, which are connected to the conductive wire 22, respectively. It should be noted that in practical implementation the number of the conductive wires 22 or the distribution and shape of the first electrode layer 24 is not limited to what shown in FIG. 5.

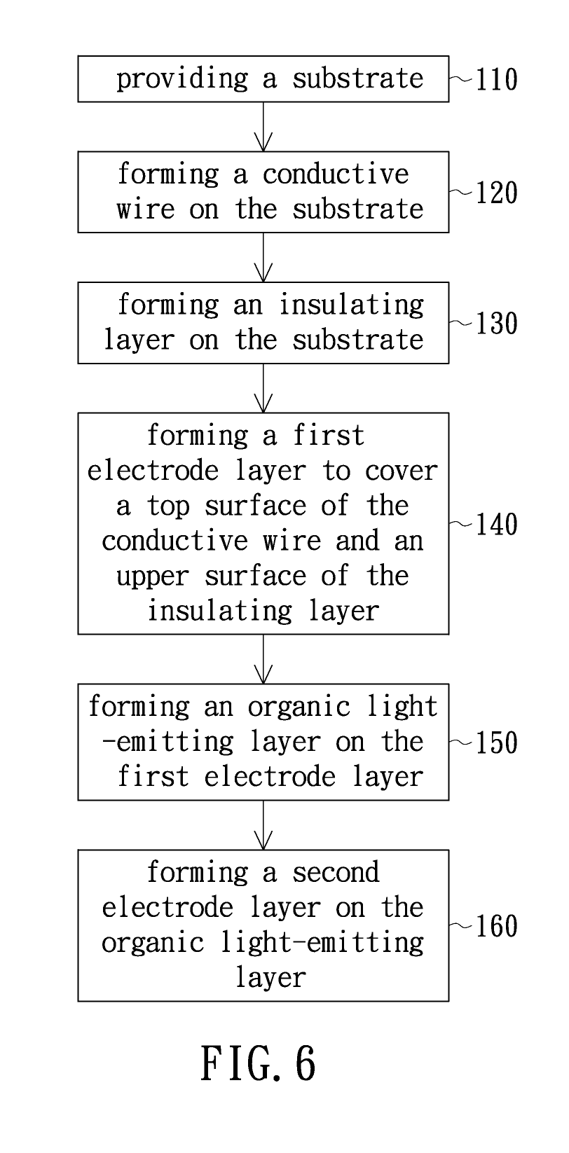

FIG. 6 is a flowchart showing a method for manufacturing an OLED lighting device 20 according to an embodiment of the invention. Referring to FIGS. 2 and 6, firstly, in step 110, a substrate 21 is provided. Next, in step 120, a conductive wire 22 is formed on the substrate 21. Then, in step 130, an insulating layer 23 is formed on the substrate 21 such that at least a part of the top surface 221 of the conductive wire 22 is exposed from the insulating layer 23. Next, in step 140, a first electrode layer 24 is formed to cover the top surface 221 of the conductive wire 22 and the upper surface 231 of the insulating layer 23, such that the first electrode layer 24 is electrically connected with the top surface 221 of the conductive wire 22. Then, in step 150, an organic light-emitting layer 25 is formed on the first electrode layer 24. Finally, in step 160, a second electrode layer 26 is formed on the organic light-emitting layer 25, so that the OLED lighting device 20 according to an embodiment of the invention is completed.

In summary, the invention has at least the following advantages:

Since the top surface 221 of the conductive wire 22 is substantially flush with the upper surface 231 of the insulating layer 23 or the upper surface of the first electrode layer 24, they constitute a substantially flat plane. In this way, the organic light-emitting layer 25 and the second electrode layer 26 extend continuously on the conductive wire 22 and the insulating layer 23 in parallel to each other. Since there is no bent part, the thickness of each of the organic light-emitting layer 25 and the second electrode layer 26 is uniform and thus cracks do not occur. In this way, a light-emitting uniformity of the OLED lighting device 20 can be effectively increased.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An organic light-emitting diode (OLED) lighting device, comprising:
a substrate;
at least a conductive wire, which is disposed on the substrate and has a top surface away from the substrate;
an insulating layer, which is disposed on the substrate and has an upper surface away from the substrate, wherein at least a part of the top surface of the conductive wire is exposed from the insulating layer;
a first electrode layer, which is disposed to cover the upper surface of the insulating layer, and is electrically connected with the conductive wire;
an organic light-emitting layer disposed on the first electrode layer; and
a second electrode layer disposed on the organic light-emitting layer.

2. The OLED lighting device according to claim 1, wherein the thickness of the insulating layer substantially equals to the thickness of the conductive wire, such that the upper surface of the insulating layer is substantially flush with the top surface of the conductive wire, and a height difference between the upper surface of the insulating layer and the top surface of the conductive wire is less than 100 nm.

3. The OLED lighting device according to claim 1, wherein the thickness sum of the insulating layer and the first electrode layer is substantially equal to the thickness of the conductive wire, such that the upper surface of the first electrode layer is substantially flush with the top surface of the conductive wire.

4. The OLED lighting device according to claim 1, wherein the organic light-emitting layer and the second electrode layer extend continuously in parallel to each other.

5. The OLED lighting device according to claim 1, wherein the conductive wire extends linearly on the substrate.

6. The OLED lighting device according to claim 1, wherein a plurality of conductive wires are arranged in parallel on the substrate.

7. A method for manufacturing an OLED lighting device, comprising:
providing a substrate;
forming at least a conductive wire on the substrate, the conductive wire having a top surface away from the substrate;
forming an insulating layer on the substrate, the insulating layer having an upper surface away from the substrate, wherein at least a part of the top surface of the conductive wire is exposed from the insulating layer;
forming a first electrode layer to cover the upper surface of the insulating layer, such that the first electrode layer and the conductive wire are electrically connected;
forming an organic light-emitting layer on the first electrode layer; and
forming a second electrode layer on the organic light-emitting layer.

8. The method for manufacturing an OLED lighting device according to claim 7, wherein the thickness of the insulating layer is substantially equal to the thickness of the conductive wire, such that the upper surface of the insulating layer is substantially flush with the top surface of the conductive wire, and a height difference between the upper surface of the insulating layer and the top surface of the conductive wire is less than 100 nm.

9. The method for manufacturing an OLED lighting device according to claim 7, wherein the thickness sum of the insulating layer and the first electrode layer is substantially equal to the thickness of the conductive wire, such that the upper surface of the first electrode layer is substantially flush with the top surface of the conductive wire.

10. The method for manufacturing an OLED lighting device according to claim 7, wherein the organic light-emitting layer and the second electrode layer extend continuously in parallel to each other.
